(19) United States
(12) Patent Application Publication
(10) Pub. No.: US 2025/0034701 A1
(43) Pub. Date: Jan. 30, 2025

(54) METHOD, SYSTEM AND APPARATUS FOR FORMING METAL OXIDE LAYERS

(71) Applicant: ASM IP Holding B.V., Almere (NL)

(72) Inventors: Bo Yin, Redmond, WA (US); Fu Tang, Gilbert, AZ (US); Andrea Illiberi, Leuven (BE); Charles Dezelah, Helsinki (FI)

(21) Appl. No.: 18/782,198

(22) Filed: Jul. 24, 2024

Related U.S. Application Data
(60) Provisional application No. 63/529,595, filed on Jul. 28, 2023.

(51) Int. Cl. C23C 16/40; C23C 16/455; H01L 21/02

(52) U.S. Cl. CPC C23C 16/407; C23C 16/403; C23C 16/45553; H01L 21/02554; H01L 21/02565; H01L 21/0262

(57) ABSTRACT

Method, system and apparatus for forming one or more metal oxide layers on a substrate is disclosed. An example method comprises a) providing a substrate in a reaction chamber, b) flowing a first precursor comprising zinc or gallium or a combination thereof and an oxygen species into the chamber to deposit a first oxide layer on a top surface of the substrate, c) flowing a second precursor into the chamber to deposit a second oxide layer on the first oxide layer wherein the second precursor comprises aluminum having at least one R ligand and at least one L ligand, wherein the R ligand is an alkyl ligand and wherein the R ligand and the L ligand are different and repeating steps b) or c) or a combination thereof until a desired thickness of the first oxide layer or the second oxide layer, or a combination thereof is achieved.

### CROSS-REFERENCE TO RELATED APPLICATIONS

This application is a nonprovisional of, and claims priority to and the benefit of, U.S. Provisional Patent Application No. 63/529,595, filed Jul. 28, 2023 and entitled “METHOD, SYSTEM AND APPARATUS FOR FORMING METAL OXIDE LAYERS,” which is hereby incorporated by reference herein.

### FIELD OF THE DISCLOSURE

The present disclosure generally relates to the field of semiconductor processing methods and systems, and to the field of electronic devices, and in particular, methods and systems suitable for forming layers comprising a metal oxide.

### BACKGROUND OF THE DISCLOSURE

The scaling of semiconductor devices, such as, complementary metal-oxide-semiconductor (CMOS) devices, has led to significant improvements in speed and density of integrated circuits. However, conventional device scaling techniques face significant challenges for future technology nodes.

For example, one challenge has been finding a suitable conducting material for use as a gate electrode, and particularly threshold voltage shift materials, in aggressively scaled CMOS devices. Therefore, improved materials for gate electrodes are desired. In particular, such materials can include dipole shifting layers, and can be used for threshold voltage tuning.

### SUMMARY OF THE DISCLOSURE

This summary is provided to introduce a selection of concepts in a simplified form. These concepts are described in further detail in the detailed description of example embodiments of the disclosure below. This summary is not intended to necessarily identify key features or essential features of the claimed subject matter, nor is it intended to be used to limit the scope of the claimed subject matter.

In one aspect, a method for depositing one or more metal oxide layers on a substrate is disclosed. The method comprises a) providing a substrate in a reaction chamber, b) flowing a first precursor comprising zinc or gallium or a combination thereof and an oxygen species into the chamber to deposit a first oxide layer on a top surface of the substrate, c) flowing a second precursor into the chamber to deposit a second oxide layer on the first oxide layer wherein the second precursor comprises aluminum having at least one R ligand and at least one L ligand, wherein the R ligand is an alkyl ligand and wherein the R ligand and the L ligand are different and repeating steps b) or c) or a combination thereof until a desired thickness of the first oxide layer or the second oxide layer, or a combination thereof is achieved.

In some examples the first precursor may comprise one or more of a zinc alkyl, a zinc halide, a zinc beta diketonate, a zinc alkoxide, and a zinc alkylamide. In some examples the first precursor may be selected from the group consisting of diethylzinc (DEZ), dimethylzinc (DMZ), and zinc acetylacetonate (Zn(acac)2). In some examples the first precursor may comprise one or more of a gallium beta diketonate, a gallium alkoxide, a gallium alkyl, a gallium alkylamide, a gallium halide, and a gallane. In some examples the first precursor may be selected from the group consisting of gallium(III) acetylacetonate, dimethylgallium isopropoxide, gallium chloride, trimethylgallium (TMGa), tris(dimethylamido)gallium (TDMAGa), and triethylgallium (TEGa).

In some examples the second precursor formula may be AlRxLy, wherein x+y=3 or wherein the second precursor formula is Al2RxLy, wherein x+y=6. In various examples the R ligand may comprise a branched or unbranched alkyl group containing 1 to 6 carbon atoms. In various examples at least one L ligand may be an alkoxide, a dialkylamido, or an amidinate. In some examples the alkoxide L ligand may be selected from methoxide, ethoxide, 1-propoxide, isopropoxide, 1-butoxide, 2-butoxide, isobutoxide, tert-butoxide, 1-pentoxide, 2-pentoxide, 3-pentoxide, isopentoxide, tert-pentoxide, and neo-pentoxide. In some examples the dialkylamido L ligand may be selected from dimethylamido, ethylmethylamido, and diethylamido. In some examples the amidinate L ligand may be selected from N,N′-diisopropylacetamidinato, N,N′-di-tert-butylacetamidinato, N,N′-diisopropylformamidinato, and N,N′-di-tert-butylformamidinato. In some examples the L ligand may comprise a hydrocarbyl group containing 1 to 10 carbon atoms and a nitrogen (N) atom or oxygen (O) atom, or a combination thereof, bonded to an aluminum (Al) atom wherein the L ligand is bonded to the Al atom through two different atoms. In some examples the hydrocarbyl group may be branched, unbranched, cyclic, or aromatic, or a combination thereof. In some examples the thickness of the first oxide layer is about between 0.5 and 20 angstroms thick.

In some examples the first oxide layer may be a zinc oxide layer. In some examples the zinc oxide layer may comprise zinc oxide, aluminum-doped zinc oxide or indium-gallium-zinc-oxide, or a combination thereof. In some examples the first oxide layer may be a gallium oxide layer. In some examples the gallium oxide layer may comprise gallium oxide (GaO), indium gallium oxide (IGO), gallium zinc oxide (GaZnO), or indium-gallium-zinc-oxide (IGZO) or a combination thereof.

In some examples a first thickness of the second oxide layer may be deposited using the second precursor and a second thickness of the second oxide layer may be deposited using a third precursor. In some examples, the second precursor is different from the third precursor. In some examples the second oxide layer may be an aluminum oxide. In some examples the first thickness of the second oxide layer is in the range of about 1 angstrom to about 20 angstroms and a second thickness of the second oxide layer is in the range of about 0.5 to about 20 angstroms. In some examples the third precursor comprises trimethylaluminum (TMA), and wherein the second oxygen species comprises at least one of water (H2O) or ozone (O3).

For the purpose of summarizing the disclosure and the advantages achieved over the prior art, certain objects and advantages of the disclosure have been described herein above. Of course, it is to be understood that not necessarily all such objects or advantages can be achieved in accordance with any particular embodiment or example of the disclosure. Thus, for example, those skilled in the art will recognize that the examples disclosed herein can be carried out in a manner that achieves or optimizes one advantage or group of advantages as taught or suggested herein without necessarily achieving other objects or advantages as can be taught or suggested herein. All of these examples are intended to be within the scope of the disclosure. These and other embodiments will become readily apparent to those skilled in the art from the following detailed description of certain examples having reference to the attached figures, the disclosure not being limited to any particular example(s) discussed.

### BRIEF DESCRIPTION OF THE DRAWING FIGURES

While the specification concludes with claims particularly pointing out and distinctly claiming what are regarded as embodiments or examples of the disclosure, the advantages of examples of the disclosure may be more readily ascertained from the description of certain examples of the disclosure when read in conjunction with the accompanying drawings. Elements with the like element numbering throughout the figures are intended to be the same.

FIG. 1 illustrates a schematic diagram of a reactor system, in accordance with an example of the present technology.

FIG. 2 illustrates a schematic diagram of a reactor system having multiple reaction chambers, in accordance with an example of the present technology.

FIG. 3 illustrates a device structure, in accordance with an example of the present technology.

FIG. 4 illustrates a deposition method, in accordance with an example of the present technology.

FIG. 5 illustrates a deposition method, in accordance with an example of the present technology.

FIG. 6 illustrates a device structure, in accordance with an example of the present technology.

FIG. 7 illustrates a device structure, in accordance with an example of the present technology.

### DETAILED DESCRIPTION

The detailed description of various examples herein makes reference to the accompanying drawings, which show the exemplary examples by way of illustration. While these exemplary examples are described in sufficient detail to enable those skilled in the art to practice the disclosure, it should be understood that other examples may be realized and that logical, chemical, and/or mechanical changes may be made without departing from the spirit and scope of the disclosure. Thus, the detailed description herein is presented for purposes of illustration only and not of limitation. For example, the steps recited in any of the method or process descriptions can be executed in any combination and/or order and are not limited to the combination and/or order presented. Further, one or more steps from one of the disclosed methods or processes can be combined with one or more steps from another of the disclosed methods or processes in any suitable combination and/or order. Moreover, any of the functions or steps can be outsourced to or performed by one or more third parties. Furthermore, any reference to singular includes plural examples, and any reference to more than one component can include a singular example.

Although certain embodiments and examples are disclosed below, it will be understood by those in the art that the disclosure extends beyond the specifically disclosed examples and/or uses of the disclosure and obvious modifications and equivalents thereof. Thus, it is intended that the scope of the disclosure should not be limited by the particular examples described herein.

The illustrations presented herein are not meant to be actual views of any particular material, apparatus, structure, or device, but are merely representations that are used to describe examples of the disclosure.

As used herein, the term “substrate” can refer to any underlying material or materials that may be used, or upon which, a device, a circuit, or a film/layer may be formed.

As used herein, the term “atomic layer deposition” (ALD) can refer to a vapor deposition process in which deposition cycles, preferably a plurality of consecutive deposition cycles, are conducted in a process chamber. Typically, during each cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) can subsequently be introduced into the process chamber for use in converting the chemisorbed precursor to the desired material on the deposition surface. Typically, this reactant is capable of further reaction with the precursor. Further, purging steps can also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition”, “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “chemical vapor deposition” (CVD) can refer to any process wherein a substrate is exposed to one or more volatile precursors, which react and/or decompose on a substrate surface to produce a desired deposition.

As used herein, the terms “layer,” “film,” and/or “thin film” can refer to any continuous or non-continuous structures and material deposited by the methods disclosed herein. For example, “layer,” “film,” and/or “thin film” could include 2D materials, nanorods, nanotubes, or nanoparticles or even partial or full molecular layers or partial or full atomic layers or clusters of atoms and/or molecules. “Layer,” “film,” and/or “thin film” can comprise material or a layer with pinholes, but still be at least partially continuous.

Further, in this disclosure, any two numbers of a variable can constitute a workable range of the variable, and any ranges indicated can include or exclude the endpoints. Additionally, any values of variables indicated (regardless of whether they are indicated with “about” or not) can refer to precise values or approximate values and include equivalents, and can refer to average, median, representative, majority, or the like. Further, in this disclosure, the terms “including,” “constituted by” and “having” can refer independently to “typically or broadly comprising,” “comprising,” “consisting essentially of,” or “consisting of” in some examples. In this disclosure, any defined meanings do not necessarily exclude ordinary and customary meanings in some examples.

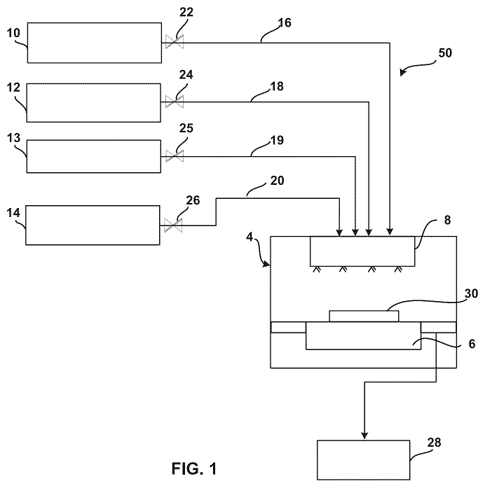

FIG. 1 illustrates a schematic diagram of a reactor system 50, in accordance with examples of the present technology. Reactor systems used for ALD, CVD, and/or the like, may be used for a variety of applications, including depositing and etching materials on a substrate surface (e.g., surface 702 and/or 704, see FIG. 7). In various examples, a reactor system 50 can comprise a reaction chamber 4, a susceptor 6 to hold a substrate 30 during processing, a fluid distribution system 8 (e.g., a showerhead) to distribute one or more reactants to a surface of substrate 30, one or more reactant sources 10, 12, 13, and/or a carrier and/or purge gas source 14, fluidly coupled to reaction chamber 4 via respective lines 16, 18, 19 and 20, and respective valves or controllers 22, 24, 25 and 26. Reactant gases or other materials from reactant sources 10, 12 and 13 can be applied to substrate 30 in reaction chamber 4. A purge gas from purge gas source 14 can be flowed to and through reaction chamber 4 to remove any excess reactant or other undesired materials from reaction chamber 4. System 50 can also comprise a vacuum source 28 fluidly coupled to the reaction chamber 4, which can be configured to evacuate reactants, a purge gas, or other materials out of reaction chamber 4.

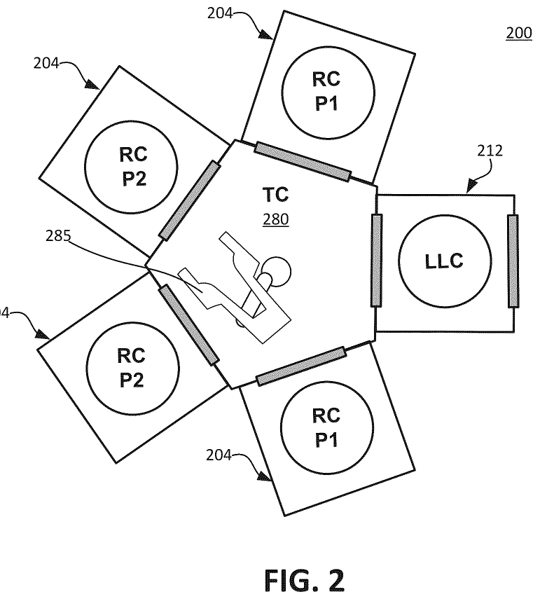

In various examples, a reactor system 50 can comprise multiple reaction chambers. For example, in reactor system 200, shown in FIG. 2, a number of reaction chambers 204 (each of which can be an example of reaction chamber 4 in FIG. 1) can be disposed around and/or coupled to a transfer chamber 280 comprising a transfer tool 285 for transferring substrates between reaction chambers 204. Substrates can be transferred from a load lock chamber 212 and between reaction chambers 204 (e.g., through transfer chamber 280). For example, a substrate 30 can be disposed in different chambers for different steps in a deposition process.

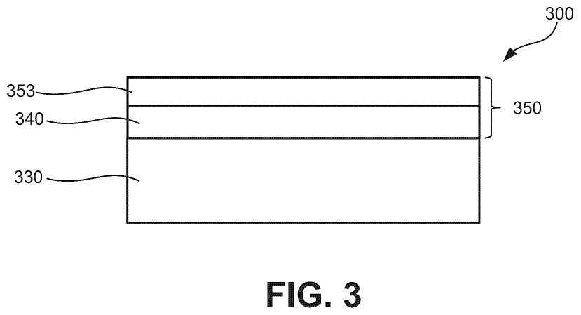

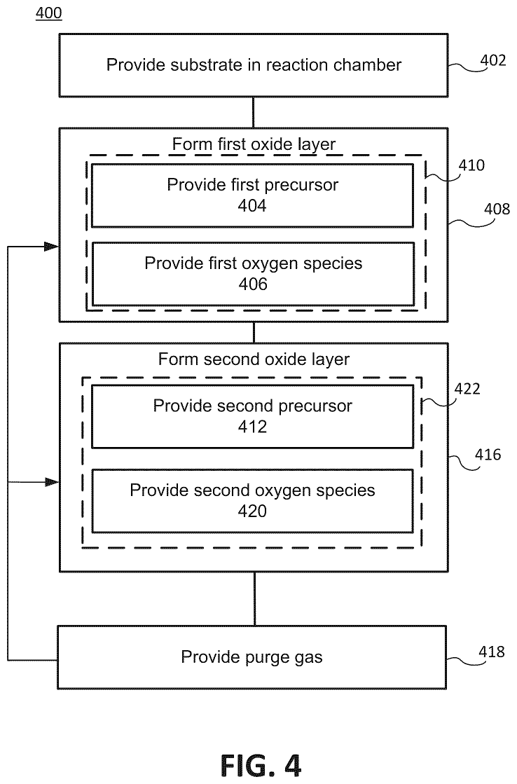

FIG. 4 depicts a method 400 of depositing layers on a substrate to form a device structure, such as device structure 300 illustrated in FIG. 3. Device structure 300 can be gate electrode structures suitable for NMOS, PMOS, and/or CMOS devices, such as for use as a p-dipole shifter in a gate, source, or drain electrode of a metal oxide semiconductor. However, unless otherwise noted, the presently described methods are not limited to such applications.

With combined reference to FIGS. 1, 3 and 4, method 400 can comprise providing a substrate 330 in a reaction chamber (step 402) (e.g., reaction chamber 4 in FIG. 1). Substrate 330 can be disposed on a susceptor (e.g., susceptor 6 in FIG. 1) for processing. In an example, the method may further comprise forming a first oxide layer 340 comprising zinc or gallium (step 408).

In an example, the first oxide layer 340 may comprise a zinc oxide (ZnO) layer and may include binary ZnO as well as ternary and quaternary zinc oxide films (e.g., aluminum-doped zinc oxide (ZnAlOx) and indium-gallium-zinc-oxide (IGZO)). In another example, the first oxide layer 340 may be a gallium oxide (GaO) layer. The gallium oxide (GaO) layer may include binary GaO as well as ternary and quaternary films containing gallium such as indium gallium oxide (IGO), gallium zinc oxide (GaZnO), and/or indium-gallium-zinc-oxide (IGZO). Other zinc or gallium containing oxides may be used and claimed subject matter is not limited in this regard.

In various examples, forming the first oxide layer 340 may comprise providing a first precursor (step 404) to the reaction chamber 4. The first precursor may comprise a zinc precursor or a gallium precursor, or a combination thereof. The first precursor may be provided to reaction chamber 4 from one or more reactant sources 10, 12 and/or 13 through showerhead 8 to substrate 330, or through a crossflow fluid distribution system. The first precursor can be pulsed into reaction chamber 4 for any suitable duration (e.g., for pulse times of between 0.05 to 100 seconds). The pressure within reaction chamber 4 during provision of the first precursor can be any suitable pressure, such as between 1 and 50 Torr.

In various examples, first oxide layer 340 may comprise a zinc oxide. In such an example, the first precursor may be any suitable zinc containing compound including but not limited to zinc alkyls, zinc halides, zinc beta diketonates, zinc alkoxides, and/or zinc alkylamides. For example, the zinc precursor may comprise diethylzinc (DEZ), dimethylzinc (DMZ), and zinc acetylacetonate (Zn(acac)2).

In various examples, the first oxide layer 340 may comprise a gallium oxide. In such an example, the first precursor may be any suitable gallium containing compound including but not limited to gallium beta diketonates, gallium alkoxides, gallium alkyls, gallium alkylamides, gallium halides, and gallanes. For example, the gallium precursor may comprise gallium(III) acetylacetonate, dimethylgallium isopropoxide, gallium chloride, trimethylgallium (TMGa), tris(dimethylamido)gallium (TDMAGa), and/or triethylgallium (TEGa).

In various examples, forming first oxide layer 340 may further comprise providing a first oxygen species (step 406) to the reaction chamber. The first oxygen species can be provided through a showerhead to the substrate, or through a crossflow fluid distribution system. The first oxygen species can be pulsed into the reaction chamber for any suitable duration (e.g., for pulse times of between 0.05 to 100 seconds). In various examples, the first oxygen species can be continuously provided to a reaction chamber 4. The pressure within the reaction chamber during provision of the first oxygen species can be any suitable pressure, such as between 1 and 50 Torr. In various examples, the first oxygen species can comprise any suitable compound comprising oxygen and/or oxidizing compound, such as water (H₂O), ozone (O₃), hydrogen peroxide (H₂O₂), deuterium oxide (D₂O), nitrous oxide (N₂O), nitrogen dioxide (NO₂), and/or an alcohol (e.g., tertbutyl alcohol), or the like or combinations thereof.

The temperature during the steps to form the first oxide layer can be between about 125° C. and 300° C., or about 200° C., or between about 250° C. and 450° C., or about 350° C. or between about 350° C. and 500° C., or about 450° C. (“about” in this context means plus or minus 50° C.).

The steps of providing the first precursor (step 404) and providing the first oxygen species (step 406) can be performed in any suitable order. In various examples, the first precursor can be provided to the reaction chamber 4 before the first oxygen species. In other examples, the first oxygen species can be provided to the reaction chamber 4 before the first precursor. In various examples, the step of providing a first precursor (step 404) and/or the step of providing a first oxygen species (step 406) can be repeated any suitable number of times before a subsequent step takes place. For example, providing the first precursor (step 404) can be repeated multiple times before or after providing the first oxygen species (step 406) to the reaction chamber, and/or providing the first oxygen species (step 406) can be repeated multiple times before or after providing the first precursor (step 404).

In various examples, the steps of providing the first precursor (step 404) and providing the first oxygen species (step 406) can be separated by a purge gas. Thus, after providing the first precursor (step 404) to the reaction chamber 4, a purge gas can be provided (step 418) to the reaction chamber 4 to remove excess precursor, byproducts, or other unwanted materials. In examples in which the first oxygen species is provided to the reaction chamber 4 before the first precursor, the purge gas can be provided (step 418) to the reaction chamber 4 after providing the first oxygen species (step 406). In various examples, a purge gas can be provided (step 418) after each step (e.g., after providing the first precursor and providing the first oxygen species, regardless of the order) and/or after deposition of the first oxide layer 340 or after a first oxide deposition cycle 410 (i.e., a post-deposition purge step). The purge gas can comprise any suitable gas, such as an inert or nonreactive gas, such as helium (He), neon (Ne), argon (Ar), krypton (Kr), xenon (Xe), and/or nitrogen (N₂).

Steps 404 and 406, and any other steps involved in forming a first oxide layer 340 (including purge steps 418) (collectively, a “first oxide deposition cycle 410”) can be repeated any suitable number of times to achieve a desired thickness of the first oxide layer 340 on the substrate 330. For example, a first oxide deposition cycle 410 can be repeated until first oxide layer 340 comprising zinc or gallium, or a combination thereof is between about 0.5 and 20 angstroms thick, or about 18 angstroms thick, or between about 1 and 16 angstroms thick, or about 14 angstroms thick, or between about 1 and 12 angstroms thick, or about 10 angstroms thick, or between about 1 and 8 angstroms thick, or about 6 angstroms thick, or between about 1 and 5 angstroms thick, or about 3 angstroms thick (“about” in this context means plus or minus two angstroms) or any other suitable thickness.

In various examples, the method 400 may further comprise forming a second oxide layer 353 (step 416) on an outer surface of the first oxide layer 340. Second oxide layer 353 may be a capping and/or protective layer and may be configured to shield or seal first oxide layer 340 from ambient fluid (e.g., oxygen in the ambient air) to minimize exposure of first oxide layer 340 to the ambient fluid.

In an example, forming second oxide layer 353 may comprise providing a second precursor to the reaction chamber 4 (step 412) after formation of the first oxide layer 340. The second precursor can be provided from one or more reactant sources 10, 12 and/or 13 through showerhead 8 to the substrate 330, or through a crossflow fluid distribution system. The second precursor can be pulsed into the reaction chamber for any suitable duration (e.g., for pulse times of between 0.05 to 100 seconds). Pulsing can be repeated any suitable number of times to achieve a desired thickness of second oxide layer 353. The pressure within the reaction chamber during provision of the second precursor can be any suitable pressure, such as between 1 and 50 Torr.

In various examples, forming second oxide layer 353 may comprise providing a second oxygen species (step 420) to the reaction chamber. The second oxygen species can be provided through showerhead 8 to the substrate 330, or through a crossflow fluid distribution system. The second oxygen species may be the same or different from the first oxygen species. The second oxygen species can be pulsed into the reaction chamber for any suitable duration (e.g., for pulse times of between 0.05 to 100 seconds). The pressure within the reaction chamber during provision of the second oxygen species can be any suitable pressure, such as between 1 and 50 Torr.

In various examples, second oxide layer 353 may cover an outer surface of the first oxide layer 340 (i.e., the surface opposite the substrate 330) such that the outer surface of the first oxide layer 340 is not exposed to ambient fluid (e.g., oxygen in ambient air) (such as the layer arrangement 350 of device structure 300 shown in FIG. 3). In various examples, the second oxide layer 353 may encapsulate the entire first oxide layer 340 (e.g., an outer surface and side surfaces of the first oxide layer). In such examples, the first oxide layer can be surrounded by the second oxide layer 353 and the substrate 330. Therefore, the second oxide layer 353 can be configured to seal at least a portion of the first oxide layer from being exposed to ambient fluid.

In an example, second oxide layer 353 can comprise any suitable compound and/or material. In various examples, second oxide layer 353 can comprise an oxide layer and/or metal oxide layer. For example, the second oxide layer 353 can comprise aluminum oxide (i.e., an aluminum oxide layer can be disposed on the zinc oxide or gallium oxide layer as a capping and/or protective layer).

Conventionally, deposition of aluminum oxide over zinc oxide or gallium oxide using aluminum containing precursor trimethylaluminum (TMA) may have deleterious effects on an underlying zinc oxide or gallium oxide (e.g., etching of zinc oxide or gallium oxide). Without being tied to any particular theory, it is believed that TMA transfers a methyl group to Zn or Ga present in the first oxide layer to form a volatile ZnMe2 or GaMe2 compound. To avoid damaging the first oxide layer 340, an aluminum containing precursor may be selected as the second precursor (in step 412) to avoid etching (e.g., by volatilization of Zn or Ga) of the first oxide layer.

In such examples, the second precursor selected to avoid or minimize damage to the first oxide layer may comprise an aluminum containing precursor of the formula AlRxLy, where R is an alkyl ligand and L is a ligand selected from alkoxide, dialkylamido, or amidinate and where x+y=3 and y>0. In an example, the group R may comprise any branched or unbranched alkyl group containing 1-6 carbon atoms. In an example, substituents on the L ligand that are attached to an atom bonded to aluminum may comprise independently any hydrocarbyl group containing 1-10 carbon atoms, including branched, unbranched, cyclic, and aromatic variants. In an example, the L ligand comprises a nitrogen (N) atom or oxygen (O) atom, or a combination thereof, bonded to an aluminum (Al) atom such that the L ligand is bonded to the Al atom through two different atoms (e.g., attached through both a carbon atom and an N or O, or a combination thereof, atom).

In some examples, the second precursor comprising an aluminum precursor may be a dimer, (i.e., having two aluminum atoms per molecule). In such an example, the second precursor (comprising an aluminum precursor) may have a formula of Al2RxLy, where x+y=6 and y>0.

In an example, the R ligand of second precursor 412 having the formula AlRxLy, may comprise alkyl ligands including but not limited to methyl, ethyl, 1-propyl, isopropyl, 1-butyl, isobutyl, 2-butyl, and tert-butyl.

In an example, the L ligand of second precursor 412 having the formula AlRxLy, may comprise alkoxide ligands including but not limited to methoxide, ethoxide, 1-propoxide, isopropoxide, 1-butoxide, 2-butoxide, isobutoxide, tert-butoxide, 1-pentoxide, 2-pentoxide, 3-pentoxide, isopentoxide, tert-pentoxide, and neo-pentoxide.

In an example, the L ligand of second precursor 412 having the formula AlRxLy, may comprise dialkylamido ligands including but not limited to dimethylamido, ethylmethylamido, and diethylamido.

In an example, the L ligand of second precursor 412 having the formula AlRxLy, may comprise amidinate ligands including but not limited N,N′-diisopropylacetamidinato, N,N′-di-tert-butylacetamidinato, N,N′-diisopropylformamidinato, and N,N′-di-tert-butylformamidinato.

In an example, the L ligand may comprise a hydrocarbyl group containing 1 to 10 carbon atoms coupled to an L ligand substituent bonded to an atom also bonded to an aluminum atom of the aluminum precursor. The hydrocarbyl group may be branched, unbranched, cyclic, or aromatic, or a combination thereof. The noted R and L ligand examples are for illustrative purposes and should not be considered as limiting the scope of possible ligands within each type.

In various examples, forming the second oxide layer may further comprise providing a second oxygen species (step 420) to a reaction chamber. The second oxygen species may be the same or different from the first oxygen species. The second oxygen species can be provided through a showerhead 8 to the substrate 330, or through a crossflow fluid distribution system. In various examples, the second oxygen species can be continuously provided to a reaction chamber. In various examples, the second oxygen species can comprise any suitable compound comprising oxygen and/or oxidizing compound, such as water (H₂O), ozone (O₃), hydrogen peroxide (H₂O₂), deuterium oxide (D₂O), nitrous oxide (N₂O), nitrogen dioxide (NO₂), and/or an alcohol (e.g., tertbutyl alcohol), or the like or combinations thereof.

The temperature during the steps to form the second oxide layer can be between about 125° C. and 300° C., or about 200° C., or between about 250° C. and 450° C., or about 350° C. or between about 350° C. and 500° C., or about 450° C. (“about” in this context means plus or minus 50° C.).

The steps of providing the second precursor (step 412) and providing the second oxygen species (step 420) can be performed in any suitable order. In various examples, the second precursor can be provided to the reaction chamber before the second oxygen species. In other examples, the second oxygen species can be provided to the reaction chamber before the second precursor. In some examples, the step of providing second precursor (step 412) and/or the step of providing the second oxygen species (step 420) can be repeated any suitable number of times before a subsequent step takes place. For example, providing the second precursor (step 412) can be repeated multiple times before or after providing the second oxygen species (step 420) to the reaction chamber, and/or providing the second oxygen species (step 420) can be repeated multiple times before or after providing the second precursor (step 412).

In various examples, the steps of providing the second precursor and providing the second oxygen species can be separated by a purge gas (step 418). Thus, after providing the second precursor (step 412) to the reaction chamber, a purge gas can be provided (step 418) to the reaction chamber to remove excess precursor, byproducts, or other unwanted materials. In examples in which the second oxygen species is provided to the reaction chamber before the second precursor, the purge gas can be provided (step 418) to the reaction chamber after providing the second oxygen species (step 420). In various examples, a purge gas can be provided (step 418) after each step (e.g., after providing the second precursor and providing the second oxygen species, regardless of the order) and/or after deposition of the second oxide layer 353 or after a second oxide deposition cycle (i.e., a post-deposition purge step). A purge gas can comprise any suitable gas, such as an inert or nonreactive gas, such as helium (He), neon (Ne), argon (Ar), krypton (Kr), xenon (Xe), and/or nitrogen (N₂).

Steps 412 and 420, and any other steps involved in forming second oxide layer 353 (including purge steps) (collectively, a “second oxide deposition cycle 422”) can be repeated any suitable number of times to achieve a desired thickness of the second oxide layer 353 on the substrate 330. For example, the second oxide deposition cycle 422 can be repeated until the second oxide layer is between about 1 and 30 angstroms thick, or about 28 angstroms thick, or about 2 and 26 angstroms thick, or about 24 angstroms thick, or between about 2.5 and 22 angstroms thick, or about 20 angstroms thick, or between about 2.5 and 18 angstroms thick, or about 16 angstroms thick, or between about 2.5 and 14 angstroms thick, or about 12 angstroms thick, or between about 2.5 and 10 angstroms thick, or about 8 angstroms thick, or between about 2.5 and 6 angstroms thick, or about 4 angstroms thick, (“about” in this context means plus or minus two angstroms) or any other suitable thickness.

In various examples, a substrate can remain in a single reaction chamber for one or more process steps discussed herein, or a substrate can be moved between reaction chambers for different process steps. For example, a substrate 330 can remain in a single reaction chamber for the first oxide deposition cycle and the second oxide deposition cycle. As another example, the first oxide deposition cycle may be performed in a first chamber and the second oxide deposition cycle may be performed in a second (different) chamber and claimed subject matter is not limited in this regard.

In various examples, forming second oxide layer 353 may comprise first providing the second precursor and subsequently providing a third precursor to one or more reaction chambers.

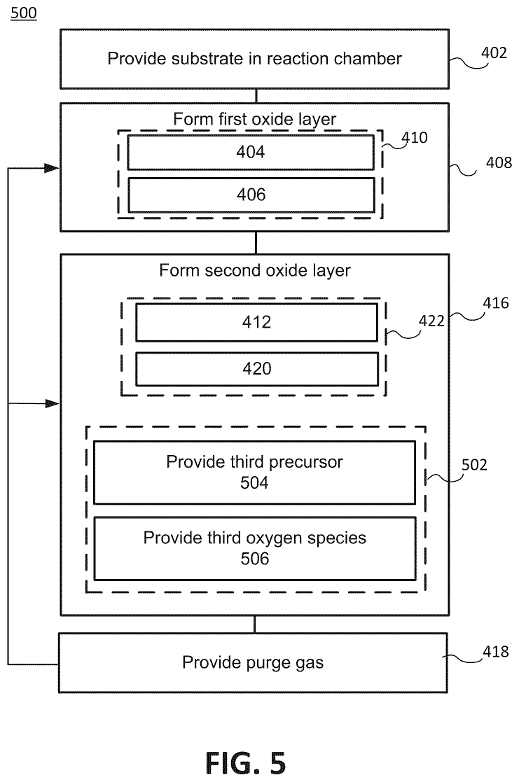

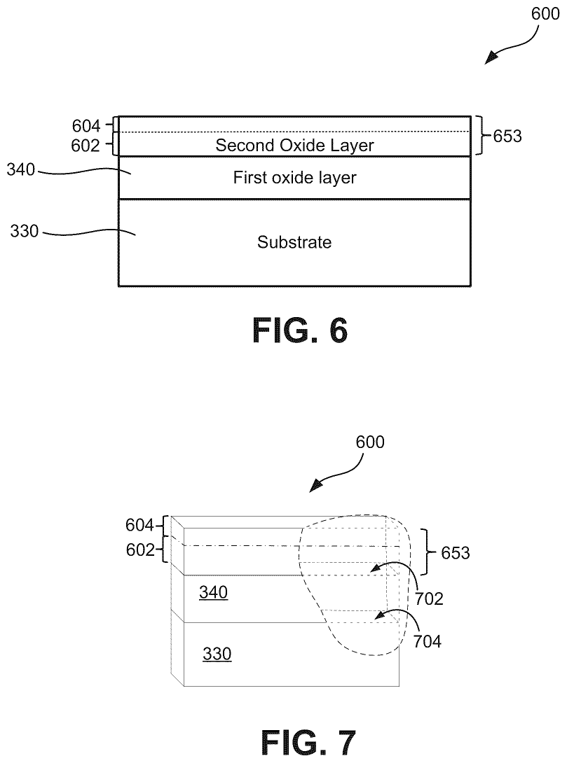

FIG. 5 depicts a method 500 of depositing layers on a substrate to form device structure 600 illustrated in FIG. 6. In structure 600, second oxide layer 353 may comprise a first thickness 602 and a second thickness 604. First thickness 602 may be formed by providing the second precursor (step 412) during the second oxide deposition cycle 422 (as described above with reference to method 400 of FIG. 4). Second thickness 604 may be formed by performing a third oxide deposition cycle 502 by providing the third precursor to the reaction chamber.

With combined reference to FIGS. 1, 5, 6, and 7 method 500 may start with providing a substrate 330 in a reaction chamber 4 (step 402).

In various examples, first oxide layer 340 may be formed by first oxide deposition cycle 410 (step 408) including steps 404, 406 and 418, as described above with reference to method 400 in FIG. 4.

In some examples, a second oxide layer 653 may comprise a first thickness 602 formed by second oxide deposition cycle 422 including steps 412, 420 and 418, as described above with reference to method 400 in FIG. 4. First thickness 602 of second oxide layer 653 (step 416) may be formed on outer surface 702 (see FIG. 7) of first oxide layer 340. First thickness 602 of second oxide layer 653 may be a capping and/or protective layer and may be configured to cover, shield, and/or seal first oxide layer 340 from ambient fluid to minimize exposure of first oxide layer 340 to various species in the ambient air to reduce risk of damage to outer surface 702.

Upon reaching a desired thickness of first thickness 602, third oxide deposition cycle 502 may begin at step 504 by providing the third precursor to the reaction chamber 4 (step 504). The third precursor can be provided from one or more reactant sources 10, 12 and/or 13 through showerhead 8 to the substrate 330, or through a crossflow fluid distribution system. The third precursor may be different from the second precursor and may be pulsed into the reaction chamber for any suitable duration (e.g., for pulse times of between 0.05 to 50 seconds). Pulsing can be repeated any suitable number of times to achieve a desired thickness of second thickness 604 of second oxide layer 653. The pressure within the reaction chamber 4 during provision of the third precursor can be any suitable pressure, such as between 1 and 50 Torr.

In various examples, second thickness 604 may be formed on the first thickness 602 of second oxide layer 653 forming an upper portion of second oxide layer 653. In an example, second thickness 604 of second oxide layer 653 can comprise any suitable compound and/or material and may comprise the same or similar material as first thickness 602. In various examples, second thickness 604 can comprise an oxide layer and/or metal oxide layer. For example, the second thickness 604 can comprise aluminum oxide.

In an example, the third precursor may be trimethylaluminum (TMA). Formation of first thickness 602 may reduce damaging effects of TMA on underlying first oxide layer 340 comprising zinc or gallium. Without being tied to any particular theory, it is believed that first thickness 602 may form a capping or protective layer and may prevent TMA from contacting first oxide layer 340 and volatilizing Zn or Ga.

In various examples, forming second thickness 604 of second oxide layer 653 may further comprise providing a third oxygen species (step 506) to a reaction chamber. The third oxygen species may be the same or different from the first and/or second oxygen species. The third oxygen species can be pulsed into the reaction chamber for any suitable duration (e.g., for pulse times of between 0.05 to 50 seconds). The pressure within the reaction chamber during provision of the third oxygen species can be any suitable pressure, such as between 1 and 10 Torr.

The third oxygen species can be provided through a showerhead 8 to the substrate 330, or through a crossflow fluid distribution system. In various examples, the third oxygen species can be continuously provided to a reaction chamber. In various examples, the third oxygen species can comprise any suitable compound comprising oxygen and/or oxidizing compound, such as water (H₂O), ozone (O₃), hydrogen peroxide (H₂O₂), deuterium oxide (D₂O), nitrous oxide (N₂O), nitrogen dioxide (NO₂), and/or an alcohol (e.g., tertbutyl alcohol), or the like or combinations thereof. In some examples where a second precursor and a third precursor are used, the third oxygen species, may comprise water (H₂O) and/or ozone (O₃).

The steps of providing the third precursor (step 504) and providing the third oxygen species (step 506) can be performed in any suitable order. In various examples, the third precursor can be provided to the reaction chamber before the third oxygen species. In other examples, the third oxygen species can be provided to the reaction chamber before the third precursor. In some examples, the step of providing third precursor (step 504) and/or the step of providing the third oxygen species (step 506) can be repeated any suitable number of times before a subsequent step takes place. For example, providing the third precursor (step 504) can be repeated multiple times before or after providing the third oxygen species (step 506) to the reaction chamber, and/or providing the third oxygen species (step 506) can be repeated multiple times before or after providing the third precursor (step 504).

In various examples, the steps of providing the third precursor and providing the third oxygen species can be separated by a purge gas (step 418). Thus, after providing the third precursor (step 504) to the reaction chamber, a purge gas can be provided (step 418) to the reaction chamber to remove excess precursor, byproducts, or other unwanted materials. In examples in which the third oxygen species is provided to the reaction chamber before the third precursor, the purge gas can be provided (step 418) to the reaction chamber after providing the third oxygen species (step 506). In various examples, a purge gas can be provided (step 418) after each step (e.g., after providing the third precursor and providing the third oxygen species, regardless of the order) and/or after deposition of the second thickness 604 of second oxide layer 353 or after the third oxide deposition cycle 502 (i.e., a post-deposition purge step). The purge gas can comprise any suitable gas, such as an inert or nonreactive gas, such as helium (He), neon (Ne), argon (Ar), krypton (Kr), xenon (Xe), and/or nitrogen (N₂).

Steps 504 and 506, and any other steps involved in forming the second thickness 604 of second oxide layer 353 (including purge steps) (collectively, the “third oxide deposition cycle 502”) can be repeated any suitable number of times to achieve a desired thickness of the second thickness 604 of second oxide layer 653. For example, third oxide deposition cycle 502 can be repeated until the second thickness 604 of second oxide layer 653 is between about 0.5 and 20 angstroms thick, or about 18 angstroms thick, or between about 1 and 16 angstroms thick, or about 14 angstroms thick, or between about 1 and 12 angstroms thick, or about 10 angstroms thick, or between about 1 and 8 angstroms thick, or about 6 angstroms thick, or between about 1and 5 angstroms thick, or about 3 angstroms thick (“about” in this context means plus or minus two angstroms) or any other suitable thickness.

In various examples, substrate 330 may remain in a single reaction chamber (e.g., chamber 4) for one or more process steps discussed herein or may be moved between reaction chambers for different process steps. For example, substrate 330 may remain in a single reaction chamber for the first oxide deposition cycle 410, the second oxide deposition cycle 422 and third oxide deposition cycle 502. In another example, no more than two of the first oxide deposition cycle 410, the second oxide deposition cycle 422 and third oxide deposition cycle 502 may be performed in the same reaction chamber. In a further example, the first oxide deposition cycle 410, the second oxide deposition cycle 422 and third oxide deposition cycle 502 may each be performed on substrate 330 in different reaction chambers. Likewise, one or more process steps of the first oxide deposition cycle 410, the second oxide deposition cycle 422 and/or third oxide deposition cycle 502 may be performed in different chambers. Claimed subject matter is not limited in this regard. In various examples, the first oxide deposition cycle 410, the second oxide deposition cycle 422 and third oxide deposition cycle 502 can be separated by a purge gas (step 418).

Although exemplary examples of the present disclosure are set forth herein, it should be appreciated that the disclosure is not so limited. Various modifications, variations, and enhancements of the system and method set forth herein may be made without departing from the spirit and scope of the present disclosure.

The subject matter of the present disclosure includes all novel and nonobvious combinations and subcombinations of the various systems, components, and configurations, and other features, functions, acts, and/or properties disclosed herein, as well as any and all equivalents thereof.

What is claimed is:

1. A method for depositing one or more metal oxide layers on a substrate, comprising:
a) providing a substrate in a reaction chamber;
b) flowing a first precursor comprising zinc or gallium or a combination thereof and an oxygen species into the chamber to deposit a first oxide layer on a top surface of the substrate;
c) flowing a second precursor into the chamber to deposit a second oxide layer on the first oxide layer wherein the second precursor comprises aluminum having at least one R ligand and at least one L ligand, wherein the R ligand is an alkyl ligand and wherein the R ligand and the L ligand are different; and
repeating steps b) or c) or a combination thereof until a desired thickness of the first oxide layer or the second oxide layer, or a combination thereof is achieved.

2. The method of claim 1, wherein the first precursor may comprise one or more of a zinc alkyl, a zinc halide, a zinc beta diketonate, a zinc alkoxide, and a zinc alkylamide.

3. The method of claim 1, wherein the first precursor is selected from the group consisting of diethylzinc (DEZ), dimethylzinc (DMZ), and zinc acetylacetonate (Zn(acac)2).

4. The method of claim 1, wherein the first precursor may comprise one or more of a gallium beta diketonate, a gallium alkoxide, a gallium alkyl, a gallium alkylamide, a gallium halide, and a gallane.

5. The method of claim 1, wherein the first precursor is selected from the group consisting of gallium(III) acetylacetonate, dimethylgallium isopropoxide, gallium chloride, trimethylgallium (TMGa), tris(dimethylamido)gallium (TDMAGa), and triethylgallium (TEGa).

6. The method of claim 1, wherein the second precursor formula is AlRxLy, wherein x+y=3 or wherein the second precursor formula is Al2RxLy, wherein x+y=6.

7. The method of claim 6, wherein at least one R ligand comprises a branched or unbranched alkyl group containing 1 to 6 carbon atoms.

8. The method of claim 6, wherein at least one L ligand is an alkoxide, a dialkylamido, or an amidinate.

9. The method of claim 8, wherein an alkoxide L ligand is selected from methoxide, ethoxide, 1-propoxide, isopropoxide, 1-butoxide, 2-butoxide, isobutoxide, tert-butoxide, 1-pentoxide, 2-pentoxide, 3-pentoxide, isopentoxide, tert-pentoxide, and neo-pentoxide.

10. The method of claim 8, wherein an dialkylamido L ligand is selected from dimethylamido, ethylmethylamido, and diethylamido.

11. The method of claim 8, wherein an amidinate L ligand is selected from N,N′-diisopropylacetamidinato, N,N′-di-tert-butylacetamidinato, N,N′-diisopropylformamidinato, and N,N′-di-tert-butylformamidinato.

12. The method of claim 8, wherein at least one of the one or more L ligands comprises a hydrocarbyl group containing 1 to 10 carbon atoms and a nitrogen (N) atom or oxygen (O) atom, or a combination thereof, bonded to an aluminum (Al) atom wherein the L ligand is bonded to the Al atom by two different atoms.

13. The method of claim 12, wherein the hydrocarbyl group is branched, unbranched, cyclic, or aromatic, or a combination thereof.

14. The method of claim 1, wherein the thickness of the first oxide layer is between 0.5 and 20angstroms thick.

15. The method of claim 1, wherein the first oxide layer is a zinc oxide layer.

16. The method of claim 15, wherein the zinc oxide layer comprises zinc oxide, aluminum-doped zinc oxide or indium-gallium-zinc-oxide, or a combination thereof.

17. The method of claim 1, wherein the first oxide layer is a gallium oxide layer.

18. The method of claim 17, wherein the gallium oxide layer comprises gallium oxide (GaO), indium gallium oxide (IGO), gallium zinc oxide (GaZnO), or indium-gallium-zinc-oxide (IGZO) or a combination thereof.

19. The method of claim 1, wherein a first thickness of the second oxide layer is deposited using the second precursor and a second thickness of the second oxide layer is deposited using a third precursor wherein the second precursor is different from the third precursor.

20. The method of claim 19. wherein the second oxide layer is an aluminum oxide.
